(19) United States
(12) Patent Application Publication
(10) Pub. No.: US 2026/0082934 A1
(43) Pub. Date: Mar. 19, 2026

(54) Methods for Providing Semi-transparent Substrate Edges

(71) Applicant: Intel Corporation, Santa Clara, CA (US)

(72) Inventors: Praveen SREERAMAGIRI, Gilbert, AZ (US); Robin McREE, Chandler, AZ (US); Jesse JONES, Chandler, AZ (US); Gang DUAN, Chandler, AZ (US); Yi LI, Chandler, AZ (US); Ibrahim EL KHATIB, Chandler, AZ (US); Srinivas PIETAMBARAM, Chandler, AZ (US)

(21) Appl. No.: 18/884,182

(22) Filed: Sep. 13, 2024

(51) Int. Cl. H01L 21/48; H01L 23/15; H01L 23/498

(52) U.S. Cl. CPC H10W 70/05; H10W 70/685; H10W 70/692

(57) ABSTRACT

According to the various aspects, the present methods provide for the laser-assisted dicing of semiconductor workpieces that produce semiconductor devices with glass cores having semi-transparent edges.

### BACKGROUND

As semiconductor technology advances, the need to improve performance and lower costs for integrated circuit design and fabrication are constant challenges. It is becoming more difficult and costly to realize high-volume manufacturing for semiconductors as transistors continue to shrink in size. Cost savings may be potentially realized by building more efficient structures and using materials that improve power performance and yields.

Presently, glass is a commonly used substrate or core for manufacturing semiconductors. It is a low-cost material with excellent properties, such as high thermal resistance, chemical resistance, high flatness, low coefficient of thermal expansion, etc. In addition, glass substrates have high smoothness and shape stability that may contribute to the prevention of yield degradation due to defects arising from various processing steps. However, glass is an amorphous material and cannot be easily etched anisotropically and/or separated into dies.

In a back-end package process, dicing is performed to divide wafers and panels into individual chips. Such individualization of a wafer or panel to multiple chips is called “singulation”, and a process of sawing a wafer plate or panel into a single cuboid is called “die sawing”. For the dicing and singulation of glass substrates, the use of a mechanical separator (e.g., cutting glass substrate with hard metal/diamond spinning blades) has traditionally been the predominant methodology, and laser cutting (e.g., using a laser beam to heat a localized area of the glass that can be cooled rapidly to induce thermal stress and create a controlled crack) has recently been used as an emerging methodology. These methods may encounter significant challenges when applied in isolation under stringent cutting conditions, especially as the height of the substrate layer stack increases with build-up (BU) layers, interconnects, devices, and other features formed on the glass substrate.

For such conditions, the stress induced by cutting may lead to glass delamination, defects propagating through the glass core resulting in “SeWaRe” (i.e., glass core splitting), breakage, and other compatibility challenges. The use of dicing and singulation processes that allow glass substrates/cores and the build-up layers thereon to be easily separated, which also provide reduced mechanical stress and thermally-induced stress, may provide lower costs and improve yields.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A through 1D show exemplary representations of a semiconductor workpiece at various stages of processing according to aspects of the present disclosure;

FIG. 2 shows an exemplary representation of a polymer ablation component of a semiconductor laser tool according to an aspect of the present disclosure;

FIG. 3 shows an exemplary representation of a laser source and an optical tuner of a semiconductor laser tool according to an aspect of the present disclosure;

FIG. 4 shows an exemplary representation of a semiconductor workpiece being diced along a cut-street according to an aspect of the present disclosure;

FIG. 5 shows a simplified flow diagram for an exemplary method according to an aspect of the present disclosure;

FIGS. 6 and 6A show exemplary scanning electron microscope images of a diced representative semiconductor workpiece according to an aspect of the present disclosure; and

FIGS. 7 and 7A show further exemplary scanning electron microscope images of a diced representative semiconductor workpiece according to aspects of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for tools and devices, and various aspects are provided for methods. It will be understood that the basic properties of the semiconductor laser tool also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present method provides a semiconductor workpiece (i.e., a partially or fully completed semiconductor panel or wafer) that has clean glass core surfaces without damaging the glass core, which is critical for the dicing/singulation process and provides modified or laser-affected zones in the glass core within cut-streets in build-up layers to produce glass core sidewalls that are semi-transparent after separation of the semiconductor workpiece. In an aspect, the present methods may “tune” a laser source to produce a laser beam having pulse widths, wavelengths, pitch, or optical properties to enable a much smoother surface on the glass core sidewalls. The tuning, for example, may be directed to reducing either the pulse width or the wavelength of a laser source to create a smaller modified or laser-affected zone in the glass core to produce smoother surfaces. In an aspect, for example, a present laser source may be tuned to have a width in a range of approximately 0.5 to 5 μm. In addition, the pitch may be tuned in a range of approximately 1 to 10 micrometers, which may be varied based on the thickness of a glass core in the semiconductor workpiece.

In an aspect, the present semiconductor laser tool may have a cutting component that includes a first laser source with a galvo-scanner, such as an ultra-violet light laser, a greenlight laser, an infrared laser, and other laser lights, which may have pulse widths that range from nanoseconds to femtoseconds, that may be used to remove the build-up layers while being able to travel through the glass core/substrate leaving it undamaged. In an aspect, a galvo-scanner uses mirror technology to move a laser beam in different directions by rotating and adjusting mirror angles within the boundaries of a work area. In an aspect, it is understood that there are compositions of glass (e.g., borosilicate glass, soda-lime glass, quartz glass, and other photosensitive glass) that will allow light to pass through them without extensive absorption, while the resins/polymers in the BU layers are relatively absorbent to these wavelengths, i.e., a present laser may be selected so that glass used will be transparent to the laser light.

In another aspect, after the BU layers are removed, a Bessel beam or filamentation technique using a second laser source may be used to modify (e. g, perforate) the glass core along the BU layer cut-streets, and this may be followed by a mechanical breaking/separation technique to complete the dicing/singulation. The second laser source may include, for example, a pulsed green laser, an infrared red (IR) laser, a carbon dioxide (CO₂) laser, an ultraviolet (UV) laser, an ultra-short pulse laser, and a diode-pumped solid-state laser. In an aspect, a present UV laser may used to produce a laser beam in a range of approximately 340 to 800 nm. In another aspect, a present IR laser may used to produce a laser beam in a range of approximately 1032 to 1064 nm.

The present disclosure provides a method for separating or dicing a semiconductor workpiece including a glass core having a first surface with first build-up (BU) layers disposed on the first surface of the glass core and second BU layers with second cut-streets disposed on the second surface of the glass core. In an aspect, first cut-streets may be formed in the first BU layer to expose the first surface of the glass core and second cut-streets may be formed in the second BU layers to expose the second surface of the glass core. In this method, a semiconductor laser tool including a laser source and filamentation perforation or Bessel perforation optics may be used to form “modified” or laser-affected zones in the glass core by directing a laser beam at the first and second cut-streets on the semiconductor workpiece. In an aspect, the laser-affected zones may be formed having a width in the range of approximately 0.5 to 5 μm. Finally, the present method includes separating/dicing the semiconductor workpiece along the laser-affected zone in the laser-affected zones using a separation component. According to the present disclosure, a modified glass core may formed by perforating, creating channels, and otherwise changing the structure of the glass core, which may include the breaking of bonds, the migrating of atoms/ions away from the treated zones, etc.

The present disclosure provides a product made by a process that is directed to separating or dicing a semiconductor workpiece including a glass core having a first surface with first build-up (BU) layers disposed on the first surface of the glass core and second BU layers with second cut-streets disposed on the second surface of the glass core. In an aspect, first cut-streets may be formed in the first BU layer to expose the first surface of the glass core and second cut-streets may be formed in the second BU layers to expose the second surface of the glass core. In this method, a semiconductor laser tool including a laser source and filamentation perforation or Bessel perforation optics may be used to form modified or laser-affected zones in the glass core by directing a laser beam at the first and second cut-streets on the semiconductor workpiece.

In an aspect, a present laser beam may form laser-affected zones having a width in the range of approximately 0.5 to 5 μm. A smaller diameter may provide improved transparency (i.e., a smoother surface) and defect control. In addition, a shorter pulse rate may result in a smaller laser-affected zone, which may be beneficial. Finally, the present method includes separating/dicing the semiconductor workpiece along the laser-affected zones in the glass core using a separation component to produce devices with glass cores that have semi-transparent edges.

The present disclosure is also directed to a device including a glass core having a first surface, a second surface, and glass sidewalls. In an aspect, the device may include first build-up (BU) layers having a first BU sidewall disposed on the first surface of the glass core and a second BU layer having a second BU sidewall disposed on the second surface of the glass core. In another aspect, wherein the glass sidewalls may have a surface roughness with a Ra of less than one micrometer and are semi-transparent.

The technical advantages of the present disclosure include, but are not limited to:
(i) providing methods that improve the separating and dicing of semiconductor panels that reduce mechanical stress and thermally-induced stress on their glass cores;
(ii) providing devices with semi-transparent glass cores that improve metrology for features in the glass cores such as through-glass vias (TGVs); and
(iii) providing improved efficiency and results for the separation of semiconductor panels and/or wafers during high-volume manufacturing.

To more readily understand and put into practical effect the present semiconductor laser tool, methods, and devices resulting therefrom, which may provide improved manufacturing yields and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

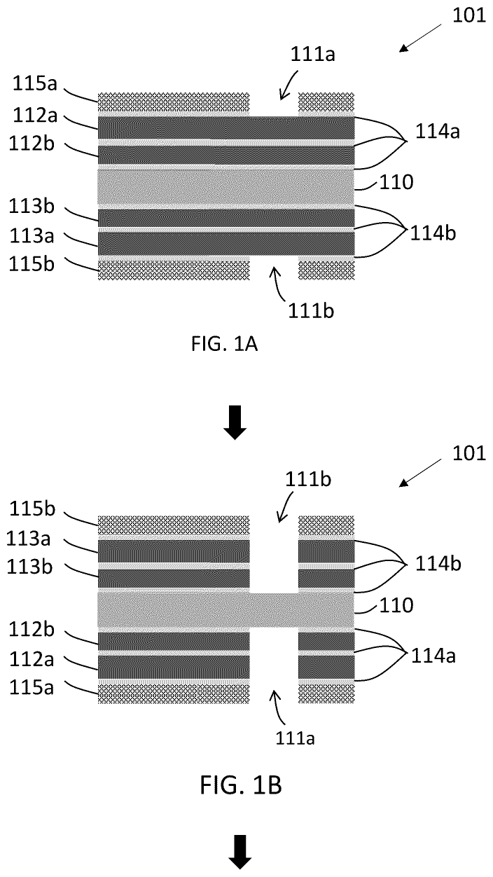

FIGS. 1A through 1D show exemplary representations of a semiconductor workpiece 101 (i.e., a partially or fully completed semiconductor panel or wafer) at various stages of processing according to aspects of the present disclosure. In FIG. 1A, the semiconductor panel 101 includes a glass core 110 having topside build-up layers 112a and 112b and backside build-up layers 113a and 113b, which may include a plurality of wiring layers made of metal lines, a.k.a., build-up wiring, that are typically separated by a compound material of glass filler and resin/polymer. A topside resist layer 115a may be disposed over the topside build-up layers 112a and a backside resist layer 115b may be disposed over the backside build-up layers 113a. It should be understood that the number of build-up layers and other layers deposited on a glass core may vary depending on a semiconductor layout design.

In an aspect, a plurality of topside insulating layers 114a may be disposed between the topside resist layer 115a, the topside build-up layers 112a, the topside build-up layers 112b, and the glass core 110, and similarly, a plurality of backside insulating layers 114b may be disposed between the backside resist layer 115b, the backside build-up layers 113a, the backside build-up layers 113b and the glass core 110. It should be understood that the number of build-up layers and other layers deposited on a glass core may vary depending on a semiconductor layout design.

In an aspect, the topside resist layer 115a may have a topside opening 111a and the backside resist layer 115b may have a backside opening 111b, which are positioned at a location for a cut-street to be used for dicing/singulation of the semiconductor panel 101. It should be understood that the semiconductor panel 101 may have a plurality of cut-streets that will need to be formed for a dicing/singulation process.

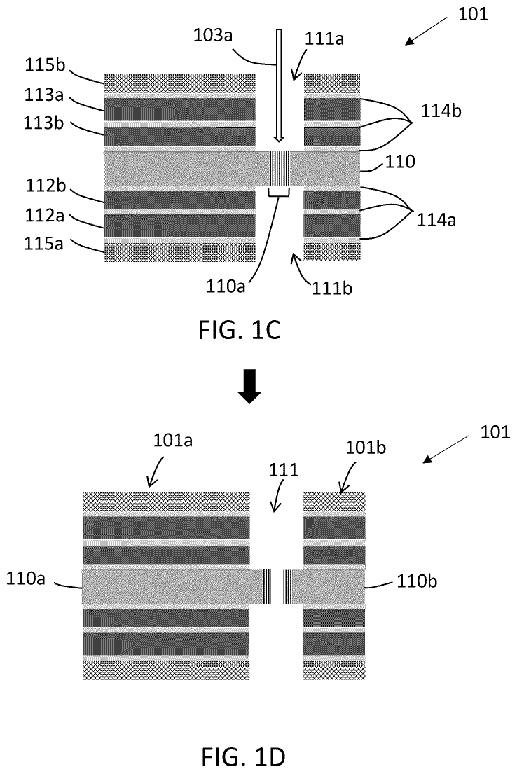

In FIG. 1B, the depth of the topside opening 111a may be further increased by a first laser step that may be used to remove the topside build-up layers 112a and 112b, as well as removing the topside insulating layers 114a and expose the glass core 110. The backside build-up layers 113b and 113a may be removed after the first laser step by turning over the semiconductor panel 101 and performing a second laser step. The first and second laser steps may be performed in a first laser operation as discussed in FIG. 2.

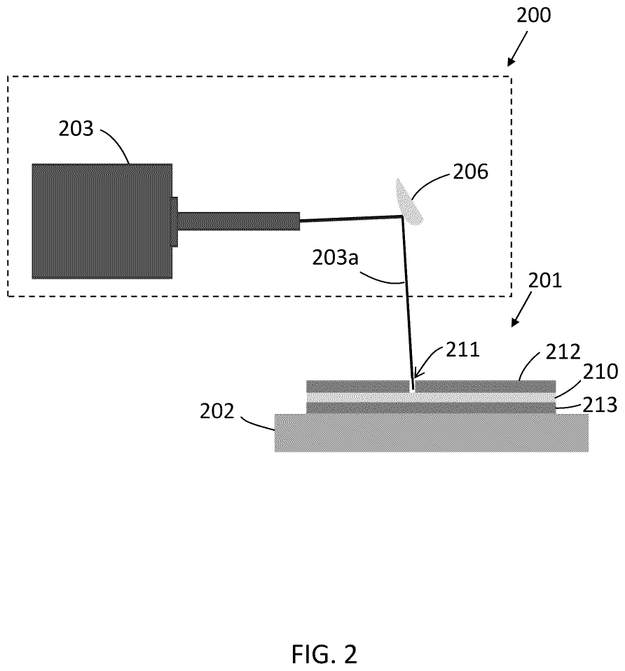

In FIG. 1C, after the removal of the topside build-up layers 112a and 112b and the backside build-up layers 113a and 113b from the semiconductor workpiece 101, the glass core 110 may be modified for dicing/singulation by a laser beam 103a to form a laser affected zone 110c in a second laser operation as discussed in FIG. 3. According to the present disclosure, a modified glass core may be formed by perforating, creating channels, and otherwise changing the structure of the glass core, which may include the breaking of bonds, the migrating of atoms/ions away from the treated zones, etc.

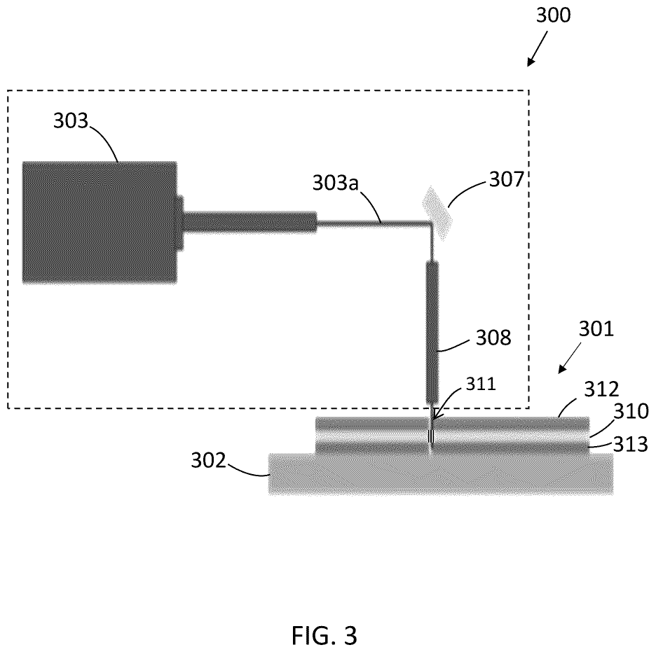

In FIG. 1D, the dicing/singulation of the semiconductor workpiece 101 may be completed by a mechanical breaking or other process, as discussed below in FIG. 4, to complete a glass cut-street 111 to form separated glass cores 110a and 110b that are part of singulated dies 101a and 101b.

In an aspect, build-up layers may have a thickness of greater than 100 μm and may typically have a thickness in the range of approximately 100 μm to 3 mm. In another aspect, a glass core may typically have a thickness in the range of approximately 200 to 1100 μm.

FIG. 2 shows exemplary representations of a first laser source 203 and a galvo-scanner 206, which may be a polymer ablation component of a semiconductor laser tool 200, according to an aspect of the present disclosure. In this aspect, a semiconductor workpiece 201 (e.g., a completed or partially completed semiconductor panel or wafer) having a glass core 210 with topside build-up layers 212 and backside build-up layers that may be positioned on a support 202. In an aspect, a suitable first laser source may be a UV-light laser, a greenlight laser, an IR laser, and other laser lights that may be used to remove build-up layers and provide a laser beam that can travel through a glass core leaving it undamaged.

FIG. 3 shows an exemplary representation of a second laser source 303 and an optical tuner 308, which may be a component of a semiconductor laser tool 300, being used to generate a laser beam 303a in a second laser operation, after the removal of polymer material from build-up layers 312 and 313 from a semiconductor workpiece 301, for dicing/singulation according to an aspect of the present disclosure. In this aspect, the laser beam 303a may be directed by a mirror 307, passed through the optical tuner 308, and directed to a glass core 310 in a BU cut-street 311 of the semiconductor workpiece 301 that is positioned on a support 302. The laser source 303 may include, for example, a pulsed green laser, an IR laser, a carbon dioxide (CO₂) laser, an ultraviolet (UV) laser, an ultra-short pulse laser, and a diode-pumped solid-state laser.

In an aspect, the optical tuner 308 may be a solid medium used to manipulate the laser beam 303a by, for example, filamentation (i.e., using a Kerr effect) to attain a self-focused beam to modify the glass core 310. In another aspect, the optical tuner 308 may include an axicon lens with axisymmetric diffraction grating to generate a Bessel beam having a very high aspect ratio, which may cause the exposed section of the glass core 310 to become more brittle. It should be understood that it is within the scope of the present disclosure to generate a Bessel beam with other lens configurations, for example, a diffractive ring lens, axisymmetric diffraction gratings, etc. In both examples, the aspect ratio of the laser beams may be controlled to ensure the whole thickness of the glass core 310 may be modified in a single shot, and this laser operation may be repeated for the lengths of the plurality of saw-streets making the dies easier to separate in a subsequent process step.

FIG. 4 shows an exemplary representation of a semiconductor workpiece 401 being diced along cut-streets 411a and 411b in topside BU layers 412 and backside BU layer 413, respectively, using the present semiconductor laser tool according to an aspect of the present disclosure. In this aspect, the semiconductor workpiece 401 may be modified by a laser using a filamentation or Bessel beam process or another similar process along the cut streets 411 section of a glass core 410. The modified section or laser-affected zone 410c of the glass core 410 along the cut street 411 may be rendered brittle and may require little force to separate the semiconductor workpieces into dies. For example, the separation may be performed by a mechanical separator such as a mechanical cleaver 420 and/or bending pins 421, which may be used individually or together as a unit. Other methods such as an additional laser separation process, breaking by pulling, and other mechanical separation methods may also be used. This additional laser separation may be performed by a third laser source, which may include, for example, a continuous wave laser, a solid-state laser, a gas laser, etc., that is included as part of a cutting component of a present semiconductor laser tool.

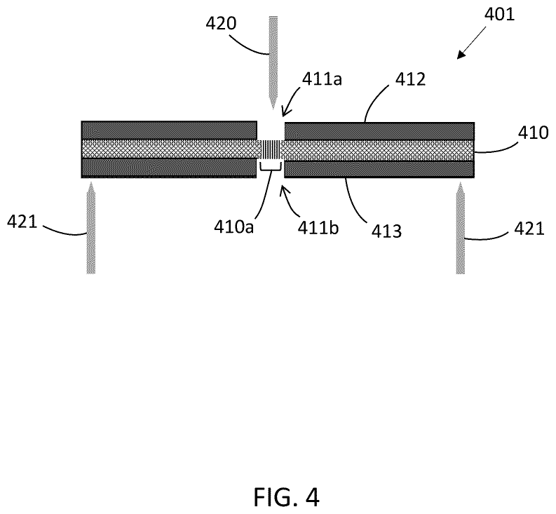

FIG. 5 shows a simplified flow diagram to outline an exemplary method 500 according to an aspect of the present disclosure.

The operation 501 may be directed to providing a semiconductor workpiece having a glass core with topside build-up layers and backside build-up layers.

The operation 502 may be directed to providing a semiconductor laser tool having a cutting component with first and second laser sources.

The operation 503 may be directed to forming cut-streets in the topside and backside build-up layers using a laser beam from the first laser source that is directed by the water from the water delivery component. This operation will remove the resin/polymer from the cut-streets without damaging the glass core.

The operation 504 may be directed to modifying the glass core along the cut-streets (e.g., perforating) using a laser beam from the second laser source and dicing the semiconductor panel thereafter (e.g., using a mechanical separator).

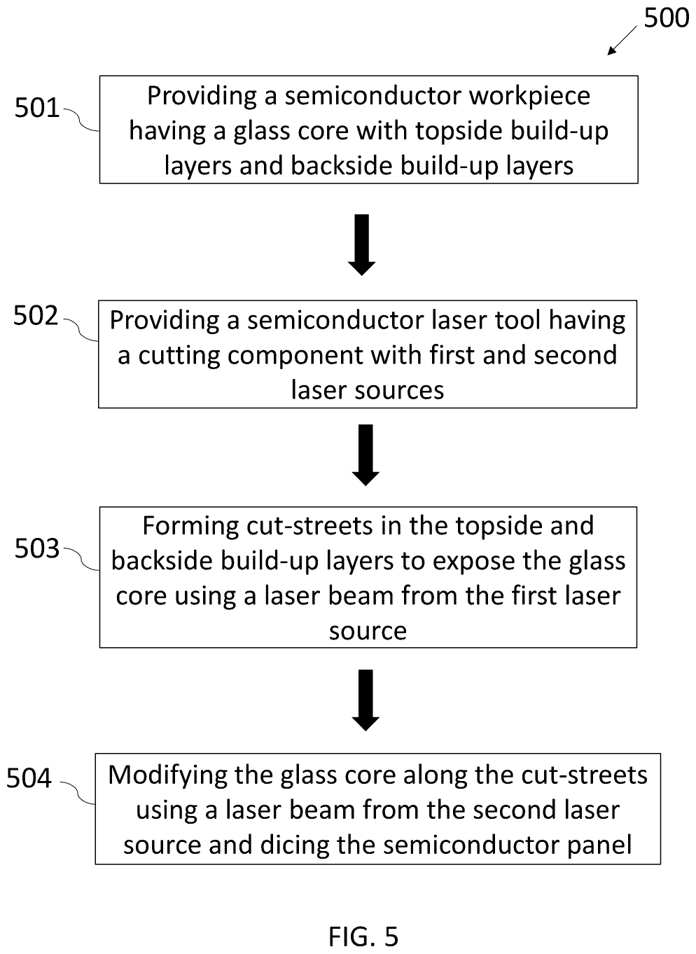

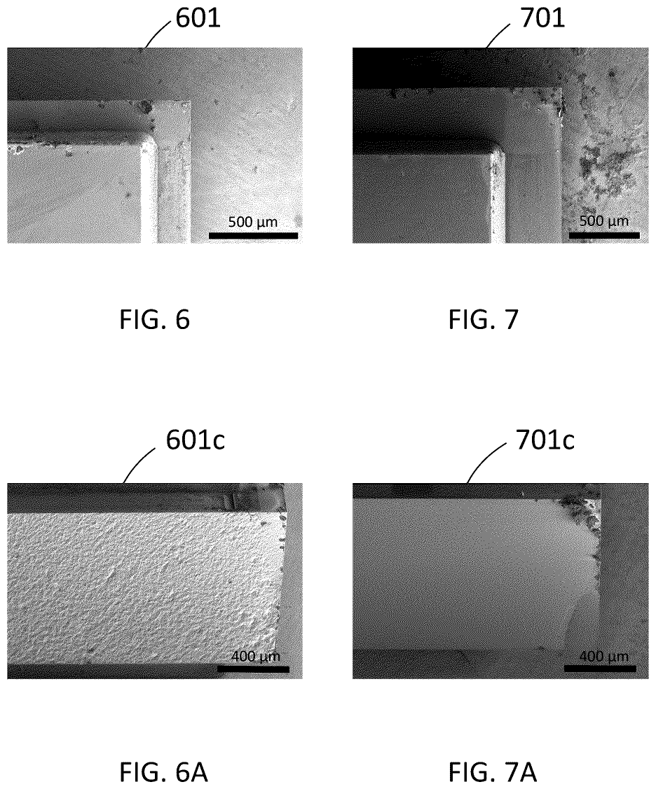

FIG. 6 and. 7 show exemplary scanning electron microscope (SEM) images of diced representative semiconductor workpieces and FIGS. 6A and 7A show corresponding SEM images of their glass sidewalls, respectively, according to aspects of the present disclosure. In FIGS. 6 and 6A, a laser singulation of a semiconductor workpiece produced a die 601, as shown in FIG. 6, using a laser operation that resulted in a glass core sidewall 601c, as shown in FIG. 6A. The glass sidewall 601c has a surface roughness (Rₐ) of several microns (e.g., a range of approximately 1 to 7 microns), which results in it being opaque. The Rₐ may be calculated by measuring the average of surface heights and depths across a measured surface.

In FIGS. 7 and 7A, a laser singulation of a semiconductor workpiece that produced a die 701, as shown in FIG. 7, using a present laser operation that includes a laser source having an optical system that is tuned and generates an enhanced Bessel beam that resulted in a sidewall 701c, as shown in FIG. 7A. In an aspect, the present methods will generally produce glass core sidewalls 701c having a surface roughness with a Rₐ of less than one (1) micrometer, which results in it being semitransparent.

It will be understood that any property described herein for a particular method for dicing and singulation using laser-assisted cutting for a semiconductor panel may also hold for any semiconductor wafer using the present methods described herein. It will also be understood that any property described herein for a specific method may hold for any of the methods described herein. Furthermore, it will be understood that for the methods described herein, not necessarily all the operations described will be shown in the accompanying drawings or method, but only some (not all) components or operations may be disclosed.

To more readily understand and put into practical effect the laser cutting of semiconductor panels and wafers using the present methods, they will now be described by way of examples. For the sake of brevity, duplicate descriptions of features and properties may be omitted.

### EXAMPLES

Example 1 provides a method that includes providing a semiconductor workpiece having a glass core having a first surface and a second surface. In an aspect, the semiconductor workpiece includes first build-up (BU) layers with first cut-streets disposed on the first surface of the glass core, for which the first cut-streets expose the first surface of the glass core and second BU layers with second cut-streets disposed on the second surface of the glass core, for which the second cut-streets expose the second surface of the glass core. In an aspect, the method further includes providing a semiconductor laser tool that includes a laser source and filamentation perforation or Bessel perforation optics that are used for forming laser-affected zones in the glass core by directing a laser beam at the first and second cut-streets on the semiconductor workpiece and thereafter dicing the semiconductor workpiece along the laser-affected zones using a separation component.

Example 2 may include the method of example 1 and/or any other example disclosed herein, for which the semiconductor laser tool forms laser-affected zones having a width in a range of approximately 0.5 to 5 micrometers.

Example 3 may include the method of example 1 and/or any other example disclosed herein, for which the semiconductor laser tool forms laser-affected zones that have a width of approximately less than one (1) micrometer.

Example 4 may include the method of example 1 and/or any other example disclosed herein, for which the laser source includes a UV-light laser, a greenlight laser, or an IR laser.

Example 5 may include the method of example 1 and/or any other example disclosed herein, for which the laser source provides the laser beam with a pitch in a range of approximately 1 to 10 micrometers.

Example 6 may include the method of example 1 and/or any other example disclosed herein, for which the semiconductor laser tool further includes a polymer ablation component including a glass transparent laser source and a glavo-scanner, and for which the method further includes using the glass transparent laser source to form the first cut-streets in the first BU layers and forming the second cut-streets in the second BU layers.

Example 7 may include the method of example 6 and/or any other example disclosed herein, which further includes forming the first cut-streets in the first BU layers, turning over the semiconductor workpiece, and thereafter forming the second cut-streets in the second BU layers.

Example 8 may include the method of example 1 and/or any other example disclosed herein, for which the separation component for dicing the semiconductor workpiece along the laser-affected zones is a mechanical separator.

Example 9 may include the method of example 1 and/or any other example disclosed herein, for which the separation component for dicing the semiconductor workpiece along the laser-affected zones is a laser separator.

Example 10 provides a product made by a process that includes providing a semiconductor workpiece having a glass core having a first surface and a second surface. In an aspect, the semiconductor workpiece includes first BU layers with first cut-streets disposed on the first surface of the glass core, for which the first cut-streets expose the first surface of the glass core and second BU layers with second cut-streets disposed on the second surface of the glass core, for which the second cut-streets expose the second surface of the glass core. In an aspect, the method further includes providing a semiconductor laser tool that includes a laser source with filamentation perforation or Bessel perforation optics, and a polymer ablation component is used to form laser-affected zones in the glass core by directing a laser beam at the first and second cut-streets on the semiconductor workpiece and thereafter dicing the semiconductor workpiece along the laser-affected zones using a separation component to produce devices with glass cores having semi-transparent edges.

Example 11 may include the product of example 10 and/or any other example disclosed herein, for which the semiconductor laser tool forms laser-affected zones having a width in a range of approximately 0.5 to 5 micrometers.

Example 12 may include the product of example 10 and/or any other example disclosed herein, for which the semiconductor laser tool forms laser-affected zones having a width of approximately less than one micrometer.

Example 13 may include the product of example 10 and/or any other example disclosed herein, for which the laser source includes a UV-light laser, a greenlight laser, or an IR laser.

Example 14 may include the product of example 10 and/or any other example disclosed herein, for which the laser beam is provided at a pitch in a range of approximately 1 to 10 micrometers.

Example 15 may include the product of example 10 and/or any other example disclosed herein, which further includes forming the first cut-streets in the first BU layers and forming the second cut-streets in the second BU layers using the polymer ablation component, for which the polymer ablation component includes a glass transparent laser source and a glavo-scanner.

Example 16 may include the product of example 10 and/or any other example disclosed herein, for which the separation component for dicing the semiconductor workpiece along the laser-affected zones is a mechanical separator.

Example 17 may include the product of example 10 and/or any other example disclosed herein, for which the separation component for dicing the semiconductor workpiece along the laser-affected zones is a laser separator.

Example 18 may include the product of example 10 and/or any other example disclosed herein, for which the diced semiconductor workpiece includes glass sidewalls having a surface roughness with a Ra of less than one (1) micrometer.

Example 19 provides a device including a glass core having a first surface, a second surface, and glass sidewalls. The device further includes first build-up (BU) layers having a first BU sidewall disposed on the first surface of the glass core and second BU layers having a second BU sidewall disposed on the second surface of the glass core, for which the glass sidewalls have a surface roughness with a Ra of less than one (1) micrometer.

Example 20 may include the device of example 19 and/or any other example disclosed herein, for which the glass sidewalls are semi-transparent.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise”and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A method comprising:
providing a semiconductor workpiece, wherein the semiconductor workpiece comprises:
a glass core having a first surface and a second surface; and
first build-up (BU) layers with first cut-streets disposed on the first surface of the glass core, wherein the first cut-streets expose the first surface of the glass core; and
second BU layers with second cut-streets disposed on the second surface of the glass core, wherein the second cut-streets expose the second surface of the glass core;
providing a semiconductor laser tool, wherein the semiconductor laser tool comprises a laser source and filamentation perforation or Bessel perforation optics;
forming laser-affected zones in the glass core using the semiconductor laser tool by directing a laser beam at the first and second cut-streets on the semiconductor workpiece; and
dicing the semiconductor workpiece along the laser-affected zones using a separation component.

2. The method of claim 1, wherein the semiconductor laser tool forms laser-affected zones having a width in a range of approximately 0.5 to 5 micrometers.

3. The method of claim 1, wherein the semiconductor laser tool forms laser-affected zones that have a width of approximately less than one micrometer.

4. The method of claim 1, wherein the laser source comprises a UV-light laser, a greenlight laser, or an IR laser.

5. The method of claim 1, wherein the laser source provides the laser beam with a pitch in a range of approximately 1 to 10 micrometers.

6. The method of claim 1, wherein the semiconductor laser tool further comprises a polymer ablation component comprising a glass transparent laser source and a glavo-scanner, and wherein the method further comprises using the glass transparent laser source to form the first cut-streets in the first BU layers and forming the second cut-streets in the second BU layers.

7. The method of claim 6, further comprises forming the first cut-streets in the first BU layers and turning over the semiconductor workpiece, and thereafter forming the second cut-streets in the second BU layers.

8. The method of claim 1, wherein the separation component for dicing the semiconductor workpiece along the laser-affected zones is a mechanical separator.

9. The method of claim 1, wherein the separation component for dicing the semiconductor workpiece along the laser-affected zones is a laser separator.

10. A product made by a process comprising:
providing a semiconductor workpiece, wherein the semiconductor workpiece comprises:
a glass core having a first surface and a second surface; and
first BU layers with first cut-streets disposed on the first surface of the glass core, wherein the first cut-streets expose the first surface of the glass core; and
second BU layers with second cut-streets disposed on the second surface of the glass core, wherein the second cut-streets expose the second surface of the glass core;
providing a semiconductor laser tool, wherein the semiconductor laser tool comprises a laser source with filamentation perforation or Bessel perforation optics, and a polymer ablation component;
forming laser-affected zones in the glass core using the semiconductor laser tool to direct a laser beam at the first and second cut-streets on the semiconductor workpiece; and
dicing the semiconductor workpiece along laser-affected zones using a separation component to produce devices with glass cores having semi-transparent edges.

11. The product of claim 10, wherein the semiconductor laser tool forms laser-affected zones having a width in a range of approximately 0.5 to 5 micrometers.

12. The product of claim 10, wherein the semiconductor laser tool forms laser-affected zones having a width of approximately less than one micrometer.

13. The product of claim 10, wherein the laser source comprises a UV-light laser, a greenlight laser, or an IR laser.

14. The product of claim 10, wherein the laser beam is provided at a pitch in a range of approximately 1 to 10 micrometers.

15. The product of claim 10, further comprises forming the first cut-streets in the first BU layers and forming the second cut-streets in the second BU layers using the polymer ablation component, wherein the polymer ablation component comprises a glass transparent laser source and a glavo-scanner.

16. The product of claim 10, wherein the separation component for dicing the semiconductor workpiece along the cut-streets is a mechanical separator.

17. The product of claim 10, wherein the separation component for dicing the semiconductor workpiece along the cut-streets is a laser separator.

18. The product of claim 10, wherein the diced semiconductor workpiece comprises glass sidewalls having a surface roughness with a Rₐ of less than one micrometer.

19. A device comprising:
a glass core having a first surface, a second surface, and glass sidewalls; and
first build-up (BU) layers having a first BU sidewall disposed on the first surface of the glass core and second BU layers having a second BU sidewall disposed on the second surface of the glass core, wherein the glass sidewalls have a surface roughness with a Rₐ of less than one micrometer.

20. The device of claim 19, wherein the glass sidewalls are semi-transparent.
